(19) United States
(12) Patent Application Publication
(10) Pub. No.: US 2009/0179293 A1
(43) Pub. Date: Jul. 16, 2009

(54) IMAGE SENSOR AND METHOD FOR MANUFACTURING THE SAME

(76) Inventors: Hee-Sung Shim, Gangneung-si (KR); Seoung-Hyun Kim, Pocheon-si (KR); Joon Hwang, Cheongju-si (KR); Kwang-Soo Kim, Seongnam-si (KR); Jin-Su Han, Seongnam-si (KR)

Correspondence Address: SHERR & VAUGHN, PLLC, 620 HERNDON PARKWAY, SUITE 200, HERNDON, VA, 20170, US

(21) Appl. No.: 12/344,536

(22) Filed: Dec. 28, 2008

(30) Foreign Application Priority Data
Dec. 28, 2007 (KR) 10-2007-0139742

(51) Int. Cl. H01L 31/105; H01L 31/103; H01L 21/768

(52) U.S. Cl. 257/458; 257/462; 438/98; 257/E31.061; 257/E31.057; 257/E21.575

(57) ABSTRACT

Embodiments relate to an image sensor. According to embodiments, an image sensor may include a circuitry, a first substrate, a photodiode, a metal interconnection, and an electrical junction region. The circuitry and the metal interconnection may be formed on and/or over the first substrate. The photodiode may contact the metal interconnection and may be formed on and/or over the first substrate. The circuitry may include an electrical junction region on and/or over the first substrate and a first conduction type region on and/or over the electrical junction region and connected to the metal interconnection. According to embodiments, an image sensor and a manufacturing method thereof may provide a vertical integration of circuitry and a photodiode.

The present application claims priority under 35 U.S.C. 119 to Korean Patent Application No. 10-2007-0139742 (filed on Dec. 28, 2007), which is hereby incorporated by reference in its entirety.

### BACKGROUND

An image sensor may be a semiconductor device that may convert an optical image into an electrical signal. An image sensor may be classified into categories, such as a charge coupled device (CCD) image sensor and a complementary metal oxide silicon (CMOS) image sensor (CIS).

During a fabrication process of an image sensor, a photodiode may be formed in a substrate using ion implantation. A size of a photodiode may be reduced to increase a number of pixels without increasing a chip size. This may reduce an area of a light receiving portion. Image quality may thereby be reduced.

Since a stack height may not reduce as much as a reduction in an area of a light receiving portion, a number of photons incident to a light receiving portion may also be reduced due to diffraction of light called Airy disk.

To address this limitation, a photodiode may be formed using amorphous silicon (Si). In addition, readout circuitry may be formed in a silicon (Si) substrate using a method such as wafer-to-wafer bonding, and a photodiode may be formed on and/or over readout circuitry (referred to as a three-dimensional (3D) image sensor). A photodiode may be connected with readout circuitry through a metal interconnection.

According to the related art, it may be difficult to electrically connect a photodiode to readout circuitry. That is, a metal interconnection may be formed on and/or over readout circuitry and wafer-to-wafer bonding may be performed such that a metal interconnection may contact the photodiode. Hence, a contact between a metal interconnection may be difficult, and an ohmic contact between a metal interconnection and a photodiode may be difficult.

Since both a source and a drain at both sides of a transfer transistor may be heavily doped with N-type impurities, a charge sharing phenomenon may occur. When a charge sharing phenomenon occurs, a sensitivity of an output image may be reduced and an image error may be generated. In addition, because a photo charge may not readily move between a photodiode and readout circuitry, a dark current may be generated and/or saturation and sensitivity may be reduced.

### SUMMARY

Embodiments relate to an image sensor and a manufacturing method thereof that may prevent an occurrence of charge sharing while increasing a fill factor.

Embodiments relate to an image sensor and a manufacturing method thereof that may minimize a dark current source and may prevent a reduction in saturation and sensitivity by providing a swift movement path for a photo charge between a photodiode and readout circuitry.

According to embodiments, an image sensor may include at least one of the following. A first substrate on and/or over which a circuitry including a metal interconnection may be formed. A photodiode contacting the metal interconnection and on and/or over the first substrate, where a circuitry may include an electrical junction region on and/or over the first substrate. A first conduction type region on and/or over the electrical junction region that may be connected to the metal interconnection.

According to embodiments, an image sensor may include at least one of the following. A first substrate on and/or over which a circuitry including a metal interconnection may be formed. A photodiode contacting the metal interconnection and formed on and/or over the first substrate, where the first substrate may have an upper portion doped with a second conduction type. According to embodiments, the circuitry may include at least one of the following. A transistor in the first substrate. An electrical junction region formed at one side of the transistor. A first conduction type region connected to the metal interconnection and contacting the electrical junction region.

According to embodiments, a method for manufacturing an image sensor may include at least one of the following. Forming a circuitry including a metal interconnection on and/or over a first substrate. Forming a photodiode on and/or over the metal interconnection. According to embodiments, forming the circuitry may include at least one of the following. Forming an electrical junction region in the first substrate. Forming a first conduction type region connected to the metal interconnection over the electrical junction region.

### DRAWINGS

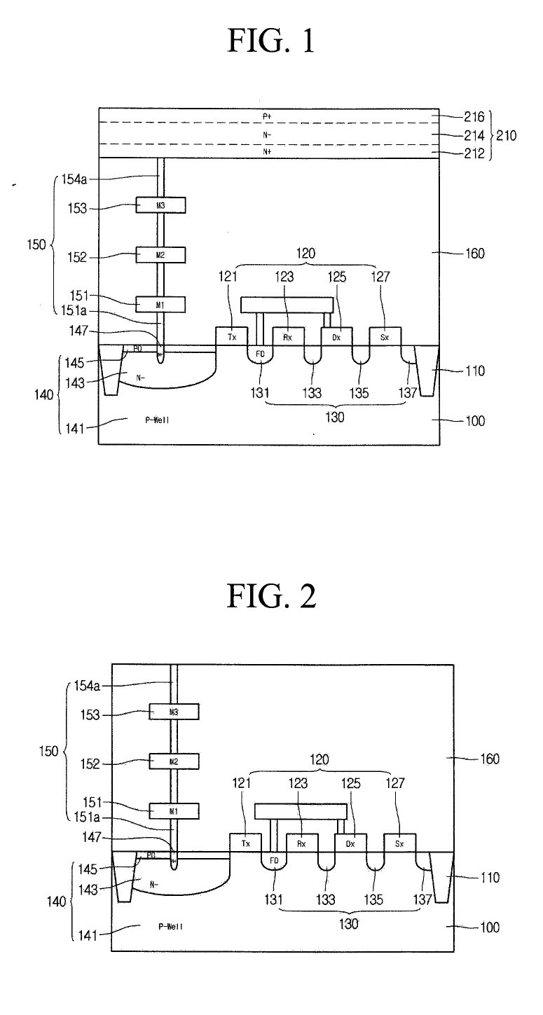

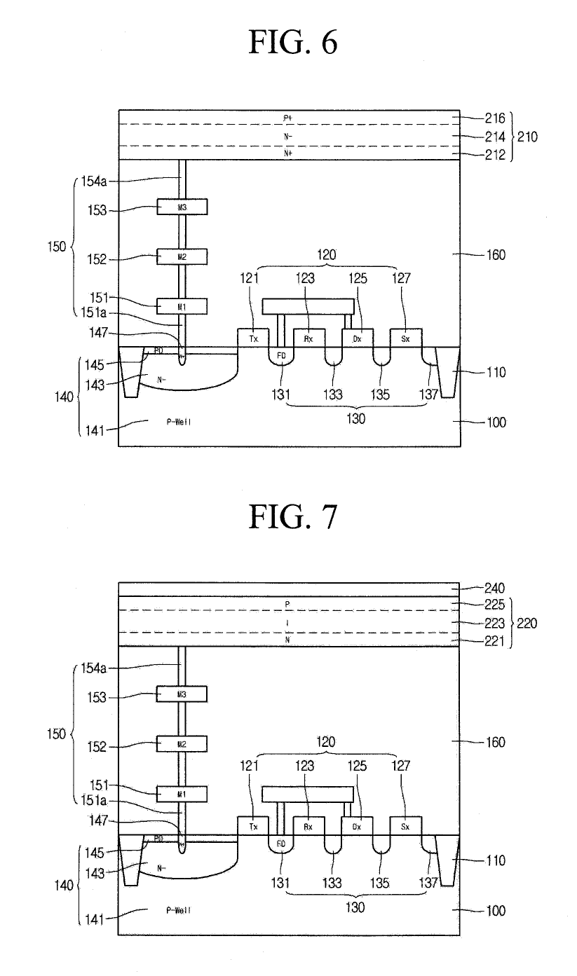

Example FIGS. 1 through 7 illustrate an image sensor and a method for manufacturing an image sensor, according to embodiments.

### DESCRIPTION

An image sensor and a method for manufacturing an image sensor in accordance with embodiments will be described with reference to the accompanying drawings.

Example FIG. 1 is a sectional view of an image sensor, according to embodiments. Referring to example FIG. 1, according to embodiments, an image sensor may include first substrate 100. Metal interconnection 150 and circuitry 120 may be formed on and/or over first substrate 100. An image sensor may also include photodiode 210 contacting metal interconnection 150. Photodiode 210 may be formed on and/or over first substrate 100. According to embodiments, circuitry 120 of first substrate 100 may include electrical junction region 140 formed in first substrate 100, and high concentration first conduction type region 147 formed on and/or over electrical junction region 140, which may be connected to metal interconnection 150.

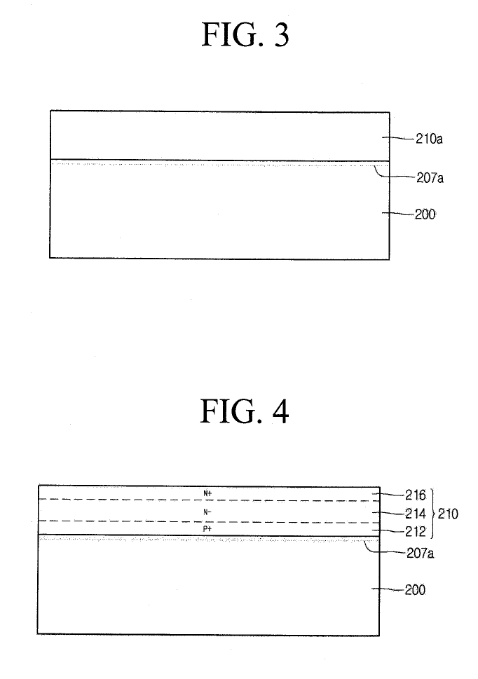

According to embodiments, photodiode 210 may be formed in crystalline semiconductor layer 210a (example FIG. 3). According to embodiments, since an image sensor may implement a vertical type photodiode where a photodiode may be positioned over a circuitry, and the photodiode may be formed in the crystalline semiconductor layer, generation of defects inside a photodiode may be prevented.

A method for manufacturing an image sensor according to embodiments will be described with reference to example FIGS. 2 to 6. Referring to example FIG. 2, a method for manufacturing an image sensor according to embodiments may include preparing first substrate 100 on and/or over which metal interconnection 150 and circuitry 120 may be formed. According to embodiments, first substrate 100 may be a second conduction type substrate. According to embodiments, first substrate 100 may be any conduction type substrate.

According to embodiments, device isolation layer 110 may be formed in second conduction type first substrate 100 and may thereby define an active region. Circuitry 120, which may include at least one transistor, may be formed in an active region. According to embodiments, circuitry 120 may include transfer transistor (Tx) 121, reset transistor (Rx) 123, drive transistor (Dx) 125 and select transistor (Sx) 127. According to embodiments, floating diffusion region (FD) 131 of ion implantation regions 130 may then be formed. Floating diffusion region (FD) 131 may include source/drain regions 133, 135, and 137 of respective transistors.

According to embodiments, forming readout circuitry 120 on and/or over first substrate 100 may include forming electrical junction region 140 in first substrate 100 and forming first conduction type connection region 147 in an upper region of electrical junction region 120. First conduction type connection region 147 may be electrically connected to metal interconnection 150. According to embodiments, electrical junction region 140 may be a PN junction. According to embodiments, electrical junction region 140 may be any junction type.

According to embodiments, electrical junction region 140 may include first conduction type ion implantation layer 143 formed on and/or over either second conduction type well 141 or a second conduction type epitaxial layer. Electrical junction region 140 may also include second conduction type ion implantation layer 145 formed on and/or over first conduction type ion implantation layer 143. According to embodiments, PN junction 140 may be a P0 (145)/N-(143)/P-(141) junction.

P0/N-/P-junction 140, which may function as a photodiode in a 4T CIS structure, may be formed in first substrate 100. Unlike a node of floating diffusion region (FD) 131, which may be an N+junction, P/N/P junction 140 may be electrical junction region to which an applied voltage may not be fully transferred. P/N/P junction 140 may thus be pinched-off at a predetermined voltage. This voltage may be called a pinning voltage, and may depend on a doping concentration of P0 region 145 and N-region 143.

According to embodiments, an electron generated by photodiode 210 may move to PNP junction 140, and may be transferred to a node of floating diffusion region (FD) 131 and converted into a voltage if transfer transistor (Tx) 121 is turned on.

A maximum voltage value of P0/N-/P-junction 140 may become a pinning voltage, and a maximum voltage value of a node of floating diffusion region (FD) 131 may become threshold voltage Vth of Vdd-Rx 123. Accordingly, an electron generated from photodiode 210 in an upper portion of a chip may be fully dumped to a node of floating diffusion region (FD) 131 without charge sharing by a potential difference between both sides of transfer transistor (Tx) 131.

According to embodiments, unlike a case where a photodiode may be simply connected to an N+ junction, limitations such as saturation reduction and sensitivity reduction may be avoided. According to embodiments, N+ layer 147 may be formed on and/or over a surface of P0/N-/P-junction 140. However, N+ layer 147 may become a leakage source. According to embodiments, to minimize a leakage source, a plug implant may be performed after first metal contact 151a may be etched. This may minimize an area of N+ layer 147, which may contribute to a decrease in a dark current of a vertical type 3-D integrated CIS.

According to embodiments, interlayer dielectric 160 may be formed on and/or over first substrate 100. According to embodiments, metal interconnection 150 may include first metal contact 151a, first metal 151, second metal 152, third metal 153, and fourth metal contact 154a.

Referring to example FIG. 3, crystalline semiconductor layer 210a may be formed on and/or over second substrate 200. According to embodiments, a photodiode may be formed in the crystalline semiconductor layer. According to embodiments, this may prevent a defect in the photodiode.

According to embodiments, crystalline semiconductor layer 210a may be formed by an epitaxial growth method on and/or over second substrate 200. According to embodiments, hydrogen ion implantation layer 207a may be formed by implanting hydrogen ions between second substrate 200 and crystalline semiconductor layer 210a. According to embodiments, an implantation of hydrogen ion may be performed after an ion implantation to form a photodiode may be performed.

Referring to example FIG. 4, impurity ions may be implanted into crystalline semiconductor layer 210a to form photodiode 210. According to embodiments, second conduction type conduction layer 216 may be formed in an upper portion of crystalline semiconductor layer 210a. According to embodiments, high concentration P-type conduction layer 216 may be formed in an upper portion of a crystalline semiconductor layer, for example by performing a first blanket-ion implantation on and/or over an entire surface of a second substrate without a mask. According to embodiments, second conduction type conduction layer 216 may be formed at a junction depth of less than approximately 0.5 μm.

According to embodiments, first conduction type conduction layer 214 may be formed under and/or below second conduction type conduction layer 216. According to embodiments, low concentration N-type conduction layer 214 may be formed under and/or below second conduction type conduction layer 216 by performing a second blanket-ion implantation on and/or over an entire surface of second substrate 200 without a mask. According to embodiments, low concentration N-type conduction layer 214 may be formed at a junction depth ranging from approximately 1.0 μm to about 2.0 μm.

According to embodiments, high concentration first conduction type conduction layer 212 may be formed under and/or below first conduction type conduction layer 214. High concentration first conduction type conduction layer 212 may be a high concentration N-type conduction layer, which may contribute to ohmic contact.

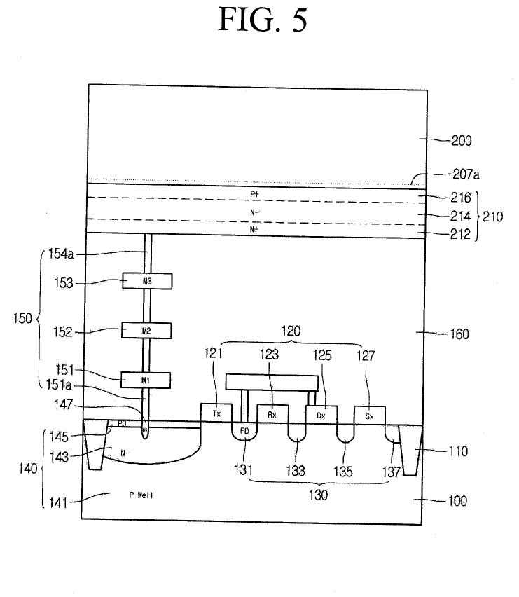

Referring to example FIG. 5, first substrate 100 and second substrate 200 may be bonded. According to embodiments, photodiode 210 may contact metal interconnection 150. According to embodiments, before first substrate 100 and second substrate 200 may be bonded to each other, a bonding may be performed by increasing the surface energy of a surface to be bonded through activation by plasma.

According to embodiments, a hydrogen ion implantation layer that may be formed in second substrate 200 may be changed into a hydrogen gas layer by performing heat treatment to second substrate 200. According to embodiments, a lower portion of second substrate 200 may be relatively easily removed from a hydrogen gas layer using a cutting apparatus such as a blade. According to embodiments, this may expose photodiode 210.

According to embodiments, an etching process may be performed. This may separate photodiode 210 for each unit pixel. An etched portion may then be filled with an interpixel dielectric. According to embodiments, processes to form an upper electrode and a color filter may then be performed.

Example FIG. 7 is a sectional view of an image sensor, according to embodiments. According to embodiments, a device illustrated in example FIG. 7 may adopt various technical characteristics of embodiments illustrated in example FIGS. 1 through 6. Unlike embodiments illustrated in example FIGS. 1 through 6, embodiments illustrated in example FIG. 7 may include photodiode 220 that may be formed in an amorphous layer.

Referring to example FIG. 7, according to embodiments, photodiode 220 may include an intrinsic layer 223 that may be electrically connected to metal interconnection 150. Photodiode 220 may also include second conduction type conduction layer 225 on and/or over intrinsic layer 223. According to embodiments, an image sensor may include first conduction type conduction layer 221, which may be formed between metal interconnection 150 and intrinsic layer 223.

A method of forming photodiode 220 according to embodiments will be described. Referring to example FIG. 7, photodiode 220 may be formed by depositing photodiode 220 on and/or over first substrate 100 on and/or over which circuitry 120 including metal interconnection 150 may be formed, and not by bonding.

According to embodiments, first conduction type conduction layer 221 may be formed on and/or over first substrate 100. According to embodiments, first conduction type conduction layer 221 may contact metal interconnection 150. According to embodiments, a subsequent process may be performed without forming first conduction type conduction layer 221. First conduction type conduction layer 221 may act as an N-layer of a PIN diode implemented in embodiments. According to embodiments, first conduction type conduction layer 221 may be an N-type conduction layer. According to embodiments, first conduction type conduction layer 221 may be any type conduction layer.

First conduction type conduction layer 221 may be formed of n-doped amorphous silicon. According to embodiments, a process may not be limited thereto. According to embodiments, first conduction type conduction layer 221 may be formed of at least one of a-Si:H, a-SiGe:H, a-SiC, a-SiN:H, and a-SiO:H, which may be formed by adding at least one of Ge, C, N, and O, to amorphous silicon. According to embodiments, first conduction type conduction layer 221 may be formed other similar compounds.

According to embodiments, first conduction type conduction layer 221 may be formed by a CVD. According to embodiments, first conduction type conduction layer 221 may be formed by a PECVD. According to embodiments, first conduction type conduction layer 141 may be formed of amorphous silicon by a PECVD in which PH3, P2H5, and/or other similar compounds may be mixed with silane (SiH4) gas.

According to embodiments, intrinsic layer 223 may be formed on and/or over first conduction type conduction layer 221. Intrinsic layer 223 may act as an I-layer of a PIN diode implemented in embodiments. According to embodiments, intrinsic layer 223 may be formed of n-doped amorphous silicon. According to embodiments, intrinsic layer 223 may be formed by a CVD. According to embodiments, Intrinsic layer 223 may be formed by a PECVD. According to embodiments, intrinsic layer 223 may be formed by a PECVD using silane (SiH4) gas.

According to embodiments, second conduction type conduction layer 225 may be formed on and/or over intrinsic layer 223. Second conduction type conduction layer 225 and intrinsic layer 223 may be formed in-situ. Second conduction type conduction layer 225 may act as a P-layer of a PIN diode employed in embodiments. According to embodiments, second conduction type conduction layer 225 may be a P-type conduction layer. According to embodiments, second conduction type conduction layer 225 may be any type conduction layer.

According to embodiments, second conduction type conduction layer 225 may be formed of Phosphorous (P)-doped amorphous silicon. According to embodiments, other processes may be used. Second conduction type conduction layer 225 may be formed by a CVD. According to embodiments, second conduction type conduction layer 225 may be formed by a PECVD. According to embodiments, second conduction type conduction layer 225 may be formed of amorphous silicon by a PECVD in which Boron (B) or another similar element may be mixed with Silane (SiH4) gas.

According to embodiments, upper electrode 240 may be formed on and/or over second conduction type conduction layer 225. Upper electrode 240 may be formed of a transparent electrode material having a high light transmission and a high conductivity. According to embodiments, upper electrode 240 may be formed of indium tin oxide (ITO), cadmium tin oxide (CTO), and/or other similar compound.

According to embodiments, an image sensor and a manufacturing method thereof may provide a vertical integration of circuitry and a photodiode. According to embodiments, a dark current source may be minimized, and saturation reduction and sensitivity reduction may be minimized or prevented by bonding a silicon substrate including a transfer transistor and a photodiode.

According to embodiments, a vertical integration of the circuitry and a photodiode may achieve a fill factor close to 100%. According to embodiments, a vertical integration of circuitry and a photodiode may provide a sensitivity higher than that in the related art with an equal pixel size.

Although embodiments may be described with respect to a complementary metal oxide semiconductor (CMOS) image sensor, embodiments may not be limited to a CIS. According to embodiments, any image sensor requiring a photodiode may be used.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A device, comprising:
a first substrate;
circuitry including a metal interconnection over the first substrate; and
a photodiode contacting the metal interconnection over the first substrate,
wherein the circuitry comprises an electrical junction region over the first substrate, and a first conduction type region over the electrical junction region and connected to the metal interconnection.

2. The device of claim 1, wherein the electrical junction region comprises:
a first conduction type ion implantation region in the first substrate; and
a second conduction type ion implantation region over the first conduction type ion implantation region.

3. The device of claim 2, wherein the electrical junction region comprises a PNP junction.

4. The device of claim 3, wherein the electrical junction region comprises a P0/N-/P-junction.

5. The device of claim 2, comprising a contact plug over the metal interconnection, wherein a width of the first conduction type ion implantation region is substantially the same as a width of the contact plug.

6. The device of claim 1, wherein the photodiode comprises a PIN diode electrically connected to the metal interconnection, and wherein a first conductive layer of the PIN diode comprises n-doped amorphous silicon.

7. The device of claim 1, wherein the photodiode is formed in a crystalline semiconductor layer and is electrically connected to the metal interconnection.

8. The device of claim 7, wherein the crystalline semiconductor layer is formed over a second substrate, and wherein the second substrate is bonded to the first substrate.

9. The device of claim 1, wherein the circuitry comprises at least one of a transfer transistor (Tx), a reset transistor (Rx), a drive transistor (Dx), and a select transistor (Sx).

10. A device, comprising:
a semiconductor substrate;
circuitry including a metal interconnection over the semiconductor substrate; and
a photodiode contacting the metal interconnection formed over the semiconductor substrate,
wherein the semiconductor substrate has an upper portion doped with a second conduction type, and the circuitry comprises:
a transistor formed in the semiconductor substrate;
an electrical junction region formed at one side of the transistor; and
a first conduction type region connected to the metal interconnection and contacting the electrical junction region.

11. The device of claim 10, wherein the electrical junction region comprises:
a first conduction type ion implantation region in the semiconductor substrate; and
a second conduction type ion implantation region over the first conduction type ion implantation region.

12. The device of claim 11, wherein the semiconductor substrate comprises an upper portion doped with P-type impurities, and the electrical junction region comprises a PN junction.

13. The device of claim 11, wherein the transistor comprises a transfer transistor.

14. The device of claim 10, wherein the circuitry comprises at least one of a transfer transistor (Tx), a reset transistor (Rx), a drive transistor (Dx), and a select transistor (Sx).

15. A method, comprising:
providing a semiconductor substrate;
forming an electrical junction region in the semiconductor substrate;
forming a metal interconnection over the semiconductor substrate;
forming a first conduction type region connected to the metal interconnection over the electrical junction region; and
forming a photodiode over the metal interconnection.

16. The method of claim 15, wherein forming the electrical junction region comprises:
forming a first conduction type ion implantation region in the semiconductor substrate; and
forming a second conduction type ion implantation region over the first conduction type ion implantation region.

17. The method of claim 16, wherein forming the electrical junction region comprises forming a PNP junction.

18. The method of claim 17, wherein the electrical junction region comprises a P0/N-/P-junction.

19. The method of claim 15, comprising forming at least one of a transfer transistor (Tx), a reset transistor (Rx), a drive transistor (Dx), and a select transistor (Sx) over the semiconductor substrate.

20. The method of claim 15, wherein the first conduction type region is formed after performing a contact etch for the metal interconnection.
